(19) United States
(12) Patent Application Publication
(10) Pub. No.: US 2025/0378883 A1
(43) Pub. Date: Dec. 11, 2025

(54) MEMORY DEVICE AND OPERATING METHOD OF THE MEMORY DEVICE

(71) Applicant: SK hynix Inc., Gyeonggi-do (KR)

(72) Inventors: Chang Beom WOO, Gyeonggi-do (KR); Moon Sik SEO, Gyeonggi-do (KR); Dae Hwan YUN, Gyeonggi-do (KR)

(21) Appl. No.: 18/963,758

(22) Filed: Nov. 29, 2024

(30) Foreign Application Priority Data
Jun. 7, 2024 (KR) 10-2024-0074466

(51) Int. Cl. G11C 16/14; G11C 16/04; G11C 16/30

(52) U.S. Cl. CPC G11C 16/14; G11C 16/0483; G11C 16/30

(57) ABSTRACT

A memory device includes cell strings coupled between bit lines and source lines, the cell strings including first select transistors, memory cells, and second select transistors; first select lines coupled to the first select transistors and spaced apart from each other in a direction in which the bit lines extend; a voltage generator configured to, during an erase operation, apply a first turn-on voltage to outer select lines among the first select lines, and apply a second turn-on voltage to inner select lines among the first select lines, the inner select lines being disposed between the outer select lines; and a control circuit configured to control, after the first turn-on voltage reaches a target level during the erase operation, the voltage generator so that the second turn-on voltage reaches a target level.

### CROSS-REFERENCE TO RELATED APPLICATION

The present application claims priority under 35 U.S.C. § 119(a) to Korean patent application number 10-2024-0074466 filed on Jun. 7, 2024, the entire disclosure of which is incorporated by reference herein.

### BACKGROUND

### 1. Technical Field

Various embodiments of the present disclosure relate generally to a memory device and a method of operating the same, and more particularly, to a three-dimensionally structured device and an erase operation thereof.

### 2. Related Art

A memory device may include a memory cell array configured to store data and a peripheral circuit configured to perform a program operation, a read operation, or an erase operation on the memory cell array.

The memory cell array may include a plurality of memory blocks. Each of the memory blocks may include a plurality of memory cells.

The peripheral circuit may include a control circuit for controlling overall operations of the memory device in response to a command (or a request) received from an external controller, and circuits configured to perform a program operation, an erase operation, or a read operation under control of the control circuit.

The conventional memory device has a two-dimensional structure in which memory cells are arranged in parallel with a substrate. Recently, however, a memory device having a three-dimensional structure with improved integration density as compared to the two-dimensionally structured memory device has been manufactured. The three-dimensionally structured memory device may include memory cells which are stacked over the substrate. For example, when memory cells stacked in a Z direction on the substrate form one cell string, a plurality of cell strings may be arranged in an X direction and a Y direction.

Since the plurality of cell strings extending in the Z direction are arranged in the X direction and the Y direction, some of the cell strings included in a memory block may be located at the edge of the memory block, and other cell strings may be located inside the memory block. Therefore, the memory cells of the memory block having the three-dimensional structure may be interfered with by its surroundings. For example, since memory cells located at an inner region of the memory block experience more interference than those located at an outer region of the memory block, channel resistance may increase in the cell strings located at the inner region of the memory block more so than those at the outer region thereof. Thus, a speed of an erase operation may vary depending on the location of the cell strings, and a width of a threshold voltage distribution of the erased memory cells may be increased. As a result, the reliability of the memory device may be degraded.

### SUMMARY

According to embodiments of the present disclosure, a width of a threshold voltage distribution of memory cells may be reduced during an erase operation by controlling a turn-on voltage applied to a drain select line according to the location of drain select lines.

According to an embodiment of the present disclosure, a memory device may include cell strings coupled between bit lines and source lines, the cell strings including first select transistors, memory cells, and second select transistors; first select lines coupled to the first select transistors and spaced apart from each other in a direction in which the bit lines extend; a voltage generator configured to, during an erase operation, apply a first turn-on voltage to outer select lines among the first select lines, and apply a second turn-on voltage to inner select lines among the first select lines, the inner select lines being disposed between the outer select lines; and a control circuit configured to control, after the first turn-on voltage reaches a target level during the erase operation, the voltage generator so that the second turn-on voltage reaches the target level.

According to an embodiment of the present disclosure, a memory device may include cell strings coupled between bit lines and source lines, the cell strings including first select transistors, memory cells, and second select transistors; first select lines coupled to the first select transistors and spaced apart from each other in a direction in which the bit lines extend; a voltage generator configured to, during an erase operation, apply a first turn-on voltage to outer select lines among the first select lines, and apply a second turn-on voltage to inner select lines among the first select lines, the inner select lines being disposed between the outer select lines; and a control circuit configured to control, before the second turn-on voltage is applied to the inner select lines during the erase operation, the voltage generator to apply a negative voltage to the inner select lines.

According to an embodiment of the present disclosure, a method of operating a memory device may include applying an erase voltage to bit lines and a source line; applying a first turn-on voltage to outer select lines among first select lines adjacent to the bit lines and arranged in a different direction from a direction in which the bit lines are arranged; and applying a second turn-on voltage to inner select lines among the first select lines, the inner select lines being disposed between the outer select lines, wherein the second turn-on voltage has a rising slope lower than a rising slope of the first turn-on voltage.

According to an embodiment of the present disclosure, a method of operating a memory device may include applying an erase voltage to bit lines and a source line; applying a ground voltage to outer select lines among first select lines adjacent to the bit lines and arranged in a different direction from a direction in which the bit lines are arranged, and applying a negative voltage to inner select lines arranged among the first select lines, the inner select lines being disposed between the outer select lines; applying a first turn-on voltage to the outer select lines to which the ground voltage is applied; and applying a second turn-on voltage to the inner select lines to which the negative voltage is applied.

### BRIEF DESCRIPTION OF THE DRAWINGS

FIG. 1 is a diagram illustrating a memory device according to an embodiment of the present disclosure;

FIG. 2 is a diagram illustrating the arrangement of a memory cell array and a peripheral circuit, according to an embodiment of the present disclosure;

FIG. 3 is a circuit diagram illustrating a memory block according to an embodiment of the present disclosure;

FIG. 4 is a diagram illustrating an increased threshold voltage distribution of memory cells during an erase operation, according to an embodiment of the present disclosure;

FIGS. 5A to 5C are diagrams illustrating outer drain select lines and inner drain select lines, according to an embodiment of the present disclosure;

FIG. 6 is a diagram illustrating an erase operation according to a first embodiment of the present disclosure;

FIG. 7 is a diagram illustrating an erase operation according to a second embodiment of the present disclosure;

FIG. 8 is a diagram illustrating the effects of an embodiment of the present disclosure;

FIG. 9 is a diagram illustrating a memory card system including a memory device according to an embodiment of the present disclosure; and

FIG. 10 is a diagram illustrating a solid state drive (SSD) system including a memory device according to an embodiment of the present disclosure.

### DETAILED DESCRIPTION

Specific structural or functional descriptions of examples of embodiments in accordance with concepts which are disclosed in this specification are illustrated only to describe the embodiments in accordance with the concepts and the embodiments in accordance with the concepts may be carried out by various forms but the descriptions are not limited to the embodiments described in this specification.

While terms such as “first” and “second” may be used to describe various components, such components must not be understood as being limited to the above terms. The above terms are used only to distinguish one component from another.

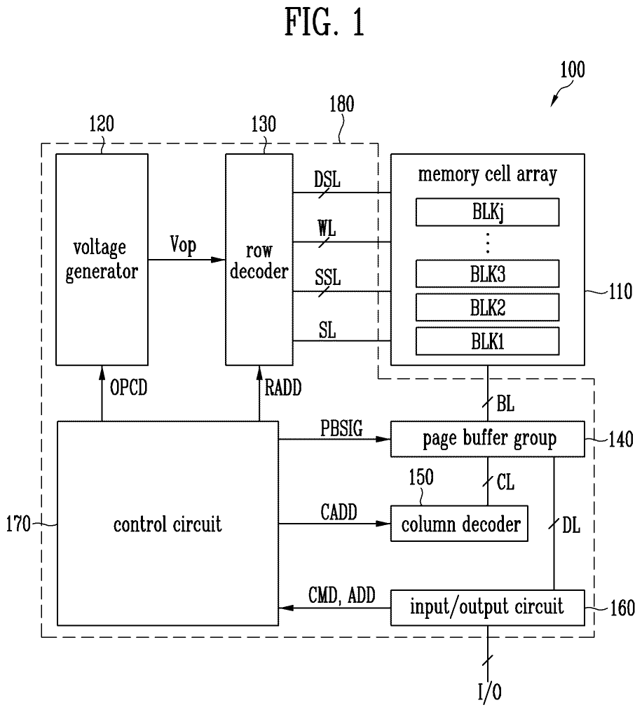

FIG. 1 is a diagram illustrating a memory device 100 according to an embodiment of the present disclosure.

Referring to FIG. 1, the memory device 100 may include a memory cell array 110 which stores data and a peripheral circuit 180 which performs a program, read, or erase operation.

The memory cell array 110 may include first to j-th memory blocks BLK1 to BLKj in which data is stored. Each of the first to j-th memory blocks BLK1 to BLKj may include a plurality of memory cells, and the memory cells may have a two-dimensional structure in which the memory cells are arranged in parallel with a substrate, or a three-dimensional structure in which the memory cells are stacked in a vertical direction to the substrate. According to an embodiment, the first to j-th memory blocks BLK1 to BLKj may have a three-dimensional structure. Drain select lines DSL, word lines WL, and source select lines SSL may be coupled to each of the first to j-th memory blocks BLK1 to BLKj. A source line SL may be commonly coupled to the first to j-th memory blocks BLK1 to BLKj.

The peripheral circuit 180 may include a voltage generator 120, a row decoder 130, a page buffer group 140, a column decoder 150, an input/output circuit 160, and a control circuit 170.

The voltage generator 120 may generate various operating voltages Vop applied to perform a program operation, a read operation, or an erase operation in response to an operation code OPCD. For example, the voltage generator 120 may generate and output a program voltage, a verify voltage, a read voltage, a pass voltage, an erase voltage, and a compensation voltage. The voltage generator 120 may control a level of each of the operating voltages Vop and a time for outputting or interrupting the operating voltages Vop in response to the operation code OPCD. According to an embodiment, the voltage generator 120 may individually control voltages applied to the drain select lines DSL in response to the operation code OPCD. For example, the voltage generator 120 may control levels of the voltages applied to the drain select lines DSL in response to the operation code OPCD.

The row decoder 130 may select one of the first to j-th memory blocks BLK1 to BLKj included in the memory cell array 110 according to a row address RADD and may transfer the operating voltages Vop to the selected memory block.

The page buffer group 140 may be coupled to the memory cell array 110 through bit lines BL. For example, the page buffer group 140 may include page buffers (not shown) coupled to the bit lines BL, respectively. The page buffers may operate at the same time in response to page buffer control signals PBSIG and temporarily store data during a program or read operation. Each of the page buffers may include a plurality of latches which temporarily store data. The number of latches may vary depending on a program method.

The column decoder 150 may transfer data DATA between the input/output circuit 160 and the page buffer group 140 in response to a column address CADD.

The input/output circuit 160 may be coupled to an external device through input/output lines IO. The input/output circuit 160 may input and output a command CMD, addresses ADD and the data DATA through the input/output lines IO. For example, the input/output circuit 160 may transfer the command CMD and the address ADD received through the input/output lines IO to the control circuit 170, and may transfer the data DATA received through the input/output lines IO to the column decoder 150. The input/output circuit 160 may output the data DATA received from the column decoder 150 to the external device.

The control circuit 170 may output the operation code OPCD, the row address RADD, the page buffer control signals PBSIG, and the column address CADD in response to the command CMD and the address ADD. For example, the control circuit 170 may consist of software for performing a program, read, or erase operation in response to the command CMD and the address ADD, and hardware for outputting the operation code OPCD, the row address RADD, the page buffer control signals PBSIG, and the column address CADD under control of the software.

During an erase operation of the selected memory block, the control circuit 170 may output the operation code OPCD such that voltages applied to drain select lines located in an outer region of the selected memory block and voltages applied to drain select lines located in an inner region of the selected memory block, among the drain select lines DSL coupled to the selected memory block, may be controlled differently.

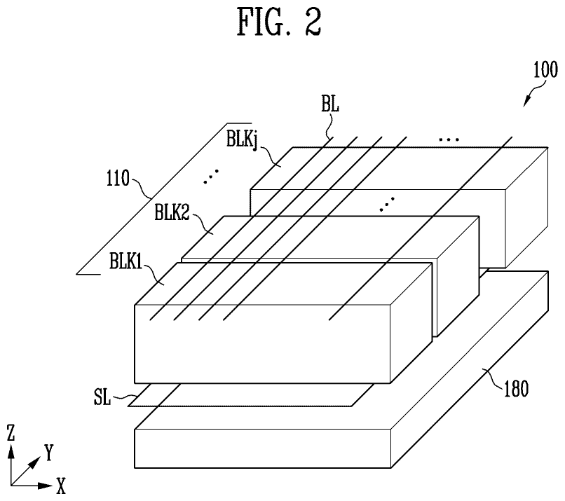

FIG. 2 is a diagram illustrating the arrangement of the memory cell array 110 and the peripheral circuit 180, according to an embodiment of the present disclosure.

Referring to FIG. 2, the memory device 100 may include the peripheral circuit 180 and the memory cell array 110. The peripheral circuit 180 may be disposed over the substrate (not shown), and the memory cell array 110 may be disposed over the peripheral circuit 180. The memory cell array 110 may include the first to j-th memory blocks BLK1 to BLKj. The bit lines BL may be disposed above the first to j-th memory blocks BLK1 to BLKj, and the source line SL may be disposed under the first to j-th memory blocks BLK1 to BLKj. However, contrary to FIG. 2, the bit lines BL may be disposed under the first to j-th memory blocks BLK1 to BLKj, and the source line SL may be disposed above the first to j-th memory blocks BLK1 to BLKj.

The plurality of bit lines BL may be spaced apart from each other in an X direction and extend in a Y direction. The first to j-th memory blocks BLK1 to BLKj may be spaced apart from each other in the Y direction. The source line SL may be commonly coupled to the first to j-th memory blocks BLK1 to BLKj.

The first to j-th memory blocks BLK1 to BLKj may have the same configuration. One of the first to j-th memory blocks BLK1 to BLKj, for example, the first memory block BLK1 will be described below in more detail.

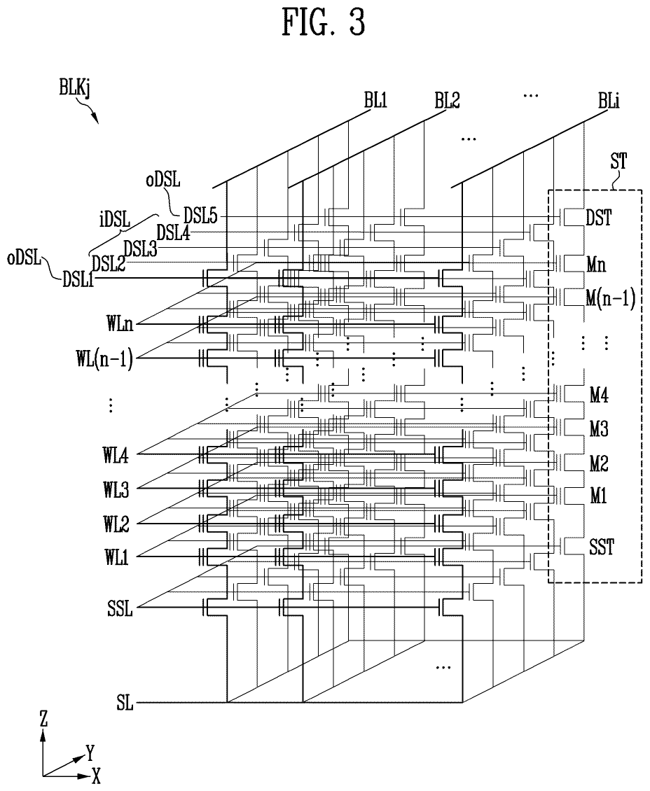

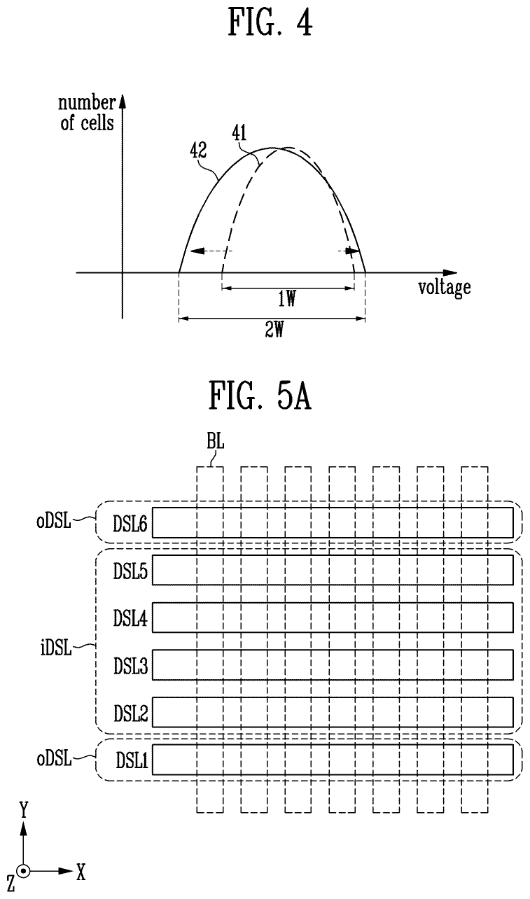

FIG. 3 is a circuit diagram illustrating a memory block according to an embodiment of the present disclosure. FIG. 4 is a diagram illustrating an increase threshold voltage distribution of memory cells during an erase operation, according to an embodiment of the present disclosure.

Referring to FIGS. 3 and 4, one of the first to j-th memory blocks BLK1 to BLKj shown in FIG. 2, for example, the j-th memory block BLKj is shown.

The j-th memory block BLKj may include cell strings ST located between the source line SL and first to i-th bit lines BL1 to BLi. The cell strings ST may be spaced apart from each other in the X and Y directions and extend in the Z direction. The first to i-th bit lines BL1 to BLi may be spaced apart from each other in the X direction, and each of the first to i-th bit lines BL1 to BLi may extend in the Y direction. FIG. 3 shows an embodiment of the j-th memory block BLKj. Thus, the number of source select transistors SST, the number of first to nth memory cells M1 to Mn, and the number of drain select transistors DST may vary depending on memory devices.

Gates of the source select transistors SST included in different cell strings ST may be coupled to the source select lines SSL. Gates of the first to nth memory cells M1 to Mn may be coupled to first to nth word lines WL1 to WLn. Gates of the drain select transistors DST may be coupled to first to fifth drain select lines DSL1 to DSL5. However, the number of drain select lines is not limited to the number shown in FIG. 3.

The source select lines SSL may be commonly coupled to the source select transistors SST arranged in the X and Y directions. However, some source select lines SSL arranged in the Y direction may be spaced apart from each other. Each of the first to nth word lines WL1 to WLn may be commonly coupled to memory cells arranged in the X and Y directions. For example, the nth memory cells Mn arranged in the X and Y directions may be commonly coupled to the nth word lines WLn, and the nth word lines WLn may be coupled to each other. For example, (n−1)th memory cells M(n−1) arranged in the X and Y directions may be commonly coupled to (n−1)th word lines WL(n−1), and the (n−1)th word lines WL(n−1) may be coupled to each other. The nth word line WLn and the (n−1)th word line WL(n−1) may be separated from each other.

The first to fifth drain select lines DSL1 to DSL5 may be separated from each other. Each of the first to fifth drain select lines DSL1 to DSL5 may be commonly coupled to the drain select transistors DST arranged in the X direction. Therefore, during a program or read operation, the selected memory cells may be included in the cell strings ST coupled to the selected drain select line among the first to fifth drain select lines DSL1 to DSL5. An erase operation may be simultaneously performed on the memory cells included in the selected memory block. Thus, all drain select lines coupled to the selected memory block may be selected drain select lines.

During the erase operation of the selected memory block, all of the first to fifth drain select lines DSL1 to DSL5 may become selected drain select lines. Therefore, during the erase operation, turn-on voltages may be applied to the first to fifth drain select lines DSL1 to DSL5. The turn-on voltages may be generated by the voltage generator 120 of FIG. 1 and be transferred to the first to fifth drain select lines DSL1 to DSL5 of the selected memory block through the row decoder 130 of FIG. 1.

During the erase operation, memory cells included in the selected memory block may be erased at the same time. Thus, memory cells located in an inner region of the selected memory block may be influenced by voltages applied to neighboring cells or lines more than memory cells located in an outer region thereof. Herein, the outer region refers to a relatively outside area of the selected memory block, and the inner region refers to a relatively inside area thereof.

Therefore, during the erase operation, the resistance of the cell strings ST located in the inner region may be higher than that of the cell strings ST located in the outer region, and the memory cells in the inner and outer regions may be erased at different speeds due to the difference in resistance. As the difference in erase speed between the memory cells increases, the erase operation of the memory block may be completed when all memory cells including memory cells with a relative low erase speed are erased. As a result, the time taken to perform the erase operation on the selected memory block may be increased. The number of memory cells influenced by the erase voltage may increase as the time taken to perform the erase operation increases. Thus, a width of a threshold voltage distribution of the memory cells may be increased.

Referring to FIG. 4, it is illustrated that a threshold voltage distribution denoted by reference numerals ‘41’ is a normal distribution. When the normal distribution 41 has a first width 1W, a threshold voltage distribution of memory cells may have a second width 2W greater than the first width 1W due to the time difference in the erase operation as in a threshold voltage distribution denoted by reference numerals ‘42’. When the threshold voltage distribution of the erased memory cells is widened, the time taken to perform a subsequent program operation may be increased, and stress applied to the memory cells may also be increased due to voltages applied during the program operation.

In an embodiment of the present disclosure to be described below, to reduce a threshold voltage difference depending on locations of the memory cells, a voltage which is applied to the first to fifth drain select lines DSL1 to DSL5 may be controlled. For example, among the first to fifth drain select lines DSL1 to DSL5, the second to fourth drain select lines DSL2 to DSL4 may be located between the first and fifth drain select lines DSL1 and DSL5. Therefore, the first and fifth drain select lines DSL1 and DSL5 may be defined as outer drain select lines oDSL and the second to fourth drain select lines DSL2 to DSL4 may be defined as inner drain select lines iDSL. As described above, a voltage applied to the inner drain select lines iDSL may be controlled because an erase operation speed of the memory cells located in the inner region of the memory block may be slower than that of the memory cells located in the outer region thereof.

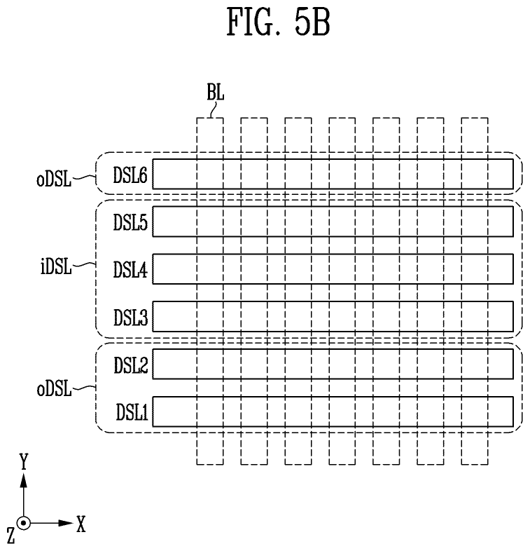

Since the memory cells included in the memory block may have different electrical characteristics, the outer drain select lines oDSL and the inner drain select lines iDSL may be set in various ways. Various methods of grouping the outer drain select lines oDSL and the inner drain select lines iDSL will be described below with reference to FIGS. 5A to 5C.

FIGS. 5A to 5C are diagrams illustrating outer drain select lines and inner drain select lines, according to an embodiment of the present disclosure.

Referring to FIGS. 5A to 5C, layout views of a memory block in which the first to sixth drain select lines DSL1 to DSL6 are coupled are shown as examples. The first to sixth drain select lines DSL1 to DSL6 may extend in an X direction and be spaced apart from each other in a Y direction. The bit lines BL may extend in the Y direction and be spaced apart from each other in the X direction.

Referring to FIG. 5A, the first and sixth drain select lines DSL1 and DSL6 located at the outermost edge among the first to sixth drain select lines DSL1 to DSL6 may be designated as the outer drain select lines oDSL, and the second to fifth drain select lines DSL2 to DSL5 located between the first and sixth drain select lines DSL1 and DSL6 may be designated as the inner drain select lines iDSL.

Referring to FIG. 5B, the first and second drain select lines DSL1 and DSL2 and the sixth drain select line DSL6 among the first to sixth drain select lines DSL1 to DSL6 may be designated as the outer drain select lines oDSL, and the third to fifth drain select lines DSL3 to DSL5 located between the second and sixth drain select lines DSL2 and DSL6 may be designated as the inner drain select lines iDSL.

Referring to FIG. 5C, the first, second, fifth, and sixth drain select lines DSL1, DSL2, DSL5, and DSL6 located at the outermost edge among the first to sixth drain select lines DSL1 to DSL6 may be designated as the outer drain select lines oDSL, and the third and fourth drain select lines DSL3 and DSL4 located between the second and fifth drain select lines DSL2 and DSL5 may be designated as the inner drain select lines iDSL.

Except the layout views shown in FIGS. 5A to 5C, the drain select lines may be grouped in various manners such that the inner drain select lines iDSL are designated between the outer drain select lines oDSL.

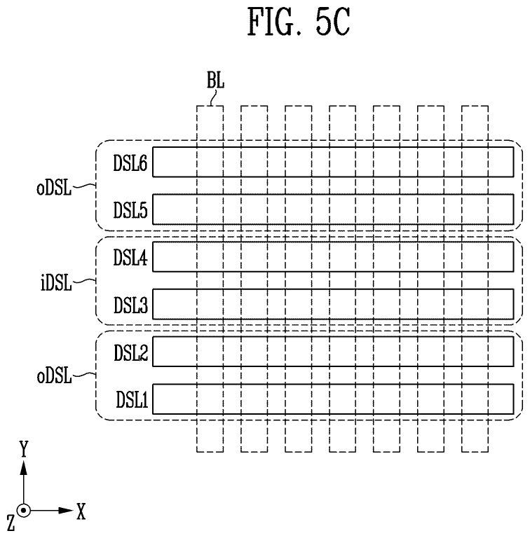

FIG. 6 is a diagram illustrating an erase operation according to a first embodiment of the present disclosure.

Referring to FIG. 6, during an erase operation, a first turn-on voltage 1Von may be applied to the outer drain select lines oDSL, and a second turn-on voltage 2Von may be applied to the inner drain select lines iDSL. Although the second turn-on voltage 2Von is set to have a target level LVt which is the same as that of the second turn-on voltage 2Von, the second turn-on voltage 2Von may increase more slowly than the first turn-on voltage 1Von. Voltages which are applied to lines during the erase operation will be described below in more detail.

At a first time T1, an erase voltage Vers may be applied to the bit lines BL and the source line SL. The erase voltage Vers applied to the bit lines BL may be generated by the page buffer group 140 of FIG. 1. The erase voltage Vers applied to the source line SL may be generated by the voltage generator 120 of FIG. 1. Before the first time T1, a ground voltage GND may be applied to the bit lines BL, the source line SL, the source select lines SSL, the outer drain select lines oDSL, the inner drain select lines iDSL, and the word lines WL. The erase voltage Vers applied to the bit lines BL and the source line SL may gradually increase from the first time T1.

At a second time T2, the first turn-on voltage 1Von may be applied to the source select lines SSL and the outer drain select lines oDSL, and the second turn-on voltage 2Von may be applied to the inner drain select lines iDSL. The first and second turn-on voltages 1Von and 2Von may be generated by the voltage generator 120 of FIG. 1. The control circuit 170 of FIG. 1 may control the voltage generator 120 of FIG. 1 to generate the first and second turn-on voltages 1Von and 2Von such that the second turn-on voltage 2Von may be increased at a slower speed than the first turn-on voltage 1Von. When a rising slope of the first turn-on voltage 1Von applied to the outer drain select lines oDSL is a first slope 1DG, the control circuit 170 of FIG. 1 may set the rising slope of the second turn-on voltage 2Von applied to the inner drain select lines iDSL to have a second slope 2DG lower than the first slope 1DG. The first and second turn-on voltages 1Von and 2Von may have the same target level LVt and different rising slopes. Thus, it may take different times for the first and second turn-on voltages 1Von and 2Von to increase to the target level LVt. Since the first turn-on voltage 1Von increases faster than the second turn-on voltage 2Von, the first turn-on voltage 1Von may increase to the target level LVt at a third time T3. At the third time T3, the second turn-on voltage 2Von may have a lower level than the target level LVt.

The voltage generator 120 of FIG. 1 may increase the level of the first turn-on voltage 1Von to the target level LVt at the third time T3 and increase the level of the second turn-on voltage 2Von to the target level LVt at a fourth time T4 later than the third time T3.

In the embodiments of the present disclosure, an erase operation of the invention may be performed using a gate induced drain leakage (GIDL) current. The GIDL current may be generated by the first turn-on voltage 1Von applied to the source select lines SSL and the outer drain select lines oDSL and the second turn-on voltage 2Von applied to the inner drain select lines iDSL. The GIDL current will be described below in more detail.

When the first turn-on voltage 1Von is applied to the source select lines SSL with the first turn-on voltage 1Von applied to the source line SL, holes of a channel of a cell string may move in a direction of a source channel region of source select transistors due to a voltage difference occurring in the source channel region. Electrons of the source channel region may move in a direction opposite to the movement direction of the holes, i.e., a channel direction of the source cell string. A GIDL current may be generated by the electrons moving in the channel direction of the cell string in the source channel region.

The GIDL current may also be generated in drain select transistors in accordance with the above principle.

Among the drain select transistors, to increase the GIDL current generated in inner drain select transistors coupled to the inner drain select lines iDSL, the voltage generator 120 of FIG. 1 may gradually increase the level of the second turn-on voltage 2Von applied to the inner drain select lines iDSL. The first turn-on voltage 1Von applied to the outer drain select lines oDSL may increase between the second time T2 and the third time T3. Thus, the GIDL current of the outer drain select transistors may occur mainly between the second time T2 and the third time T3. The second turn-on voltage 2Von applied to the inner drain select lines iDSL may increase from the second time T2 to the fourth time T4. Thus, the GIDL current may be generated in the inner drain select transistors for a longer time than in the outer drain select transistors. Therefore, more holes may flow into a drain channel region of the inner drain select transistors than that of the outer drain select transistors, so that the GIDL current may be generated for a longer time in the inner drain select transistors. When the GIDL current generated in the inner drain select transistors increases, a channel resistance of cell strings coupled to the inner drain select transistors may decrease.

Therefore, the channel resistance between the cell strings coupled to the outer drain select lines oDSL and the channel resistance between the cell strings coupled to the inner drain select lines iDSL may be similar to each other, so that a threshold voltage difference between the memory cells included in the memory block may be reduced. As a result, a width of the threshold voltage distribution of the erased memory cells may be reduced.

The memory cells in the memory block may be erased between the fourth time T4 and a fifth time T5.

At the fifth time T5, the bit lines BL, the source line SL, the source select lines SSL, the outer drain select lines oDSL, the inner drain select lines iDSL, and the word lines WL may be discharged. A potential of each of the discharged lines may decrease to the ground voltage GND.

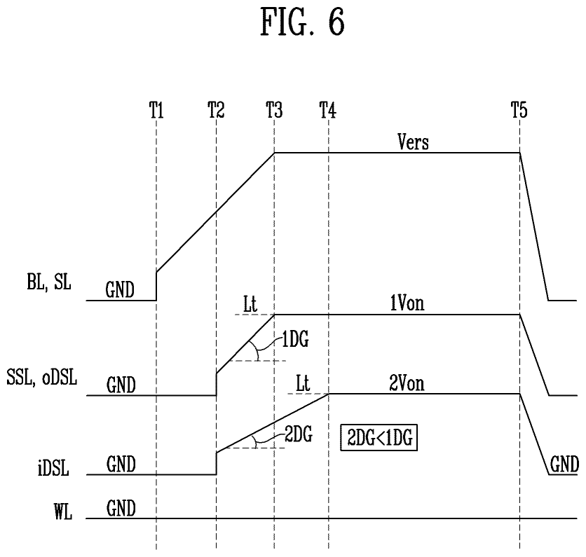

FIG. 7 is a diagram illustrating an erase operation according to a second embodiment of the present disclosure.

Referring to FIG. 7, during an erase operation, the voltage generator 120 of FIG. 1 may apply a negative voltage Vneg to the inner drain select lines iDSL before applying the second turn-on voltage 2Von to the inner drain select lines iDSL. Voltages which are applied to lines during the erase operation will be described below in more detail.

Before the first time T1, the ground voltage GND may be applied to the bit lines BL, the source line SL, the source select lines SSL, the outer drain select lines oDSL, and the word lines WL. Before the first time T1, the negative voltage Vneg lower than the ground voltage GND may be applied to the inner drain select lines iDSL.

At the first time T1, the erase voltage Vers may be applied to the bit lines BL and the source line SL. The erase voltage Vers may be set to have a positive voltage greater than the first or second turn-on voltage 1Von or 2Von. The erase voltage Vers applied to the bit lines BL and the source line SL may gradually increase from the first time T1.

At the second time T2, the first turn-on voltage 1Von may be applied to the source select lines SSL and the outer drain select lines oDSL, and the second turn-on voltage 2Von may be applied to the inner drain select lines iDSL. Before the second time T2, since the negative voltage Vneg is applied to the inner drain select lines iDSL, the potential of the inner drain select lines iDSL may increase to the target level LVt from the negative voltage Vneg. The first turn-on voltage 1Von applied to the source select lines SSL and the outer drain select lines oDSL, and the second turn-on voltage 2Von applied to the inner drain select lines iDSL may be set to increase to the target level LVt at the third time T3.

Therefore, although a GIDL current may occur at the same time in the outer drain select lines oDSL and the inner drain select lines iDSL, since the potential difference between the inner drain select lines iDSL is greater than the potential difference between the outer drain select lines oDSL, the number of holes which flow into a drain channel region of the inner drain select transistors may be greater than a number of holes which flow into a drain channel region of the outer drain select transistors. As a result, although the GIDL current may occur at the same time in the outer drain select lines oDSL and the inner drain select lines iDSL, the GIDL current in the inner drain select transistors may be greater than the GIDL current in the outer drain select transistors. When the GIDL current generated in the inner drain select transistors increases, a channel resistance of cell strings coupled to the inner drain select transistors may decrease.

Therefore, the channel resistance between the cell strings coupled to the outer drain select lines oDSL and the channel resistance between the cell strings coupled to the inner drain select lines iDSL may be similar to each other, so that a threshold voltage difference between the memory cells included in the memory block may be reduced. As a result, a width of the threshold voltage distribution of the erased memory cells may be reduced.

During the erase operation according to the second embodiment, when the first turn-on voltage 1Von applied to the outer drain select lines oDSL is increased with the first slope 1DG, the second turn-on voltage 2Von applied to the inner drain select lines iDSL may be increased with a third slope 3DG steeper than the first slope 1DG.

The memory cells in the memory block may be erased between the third time T3 and the fifth time T5.

At the fifth time T5, the bit lines BL, the source line SL, the source select lines SSL, the outer drain select lines oDSL, the inner drain select lines iDSL, and the word lines WL may be discharged. A potential of each of the discharged lines may decrease to the ground voltage GND.

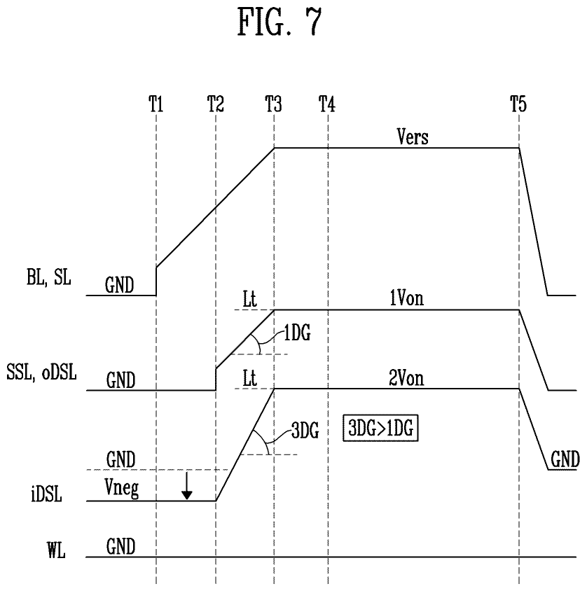

FIG. 8 is a diagram illustrating the effects of an embodiment of the present disclosure.

Referring to FIG. 8, as in the first embodiment (FIG. 6) or the second embodiment (FIG. 7) as described above, the channel resistance difference between the cell strings coupled to the outer drain select lines oDSL and the cell strings coupled to the inner drain select lines iDSL may be reduced, so that the difference in times taken to perform the erase operation on the memory cells included in the selected memory block may be reduced. Therefore, the time taken to perform the erase operation on the selected memory block may be shortened. As a result, a threshold voltage distribution 81 of the selected memory block may have a third width 3W less than a second width 2W of the existing threshold voltage distribution 82.

When the width of the threshold voltage distribution 81 of the erased memory cells is reduced, the time taken to perform a subsequent program operation may be reduced, and the reduced operation time may result in a decrease in stress applied to the memory cells. Accordingly, reliability of the memory device may be improved.

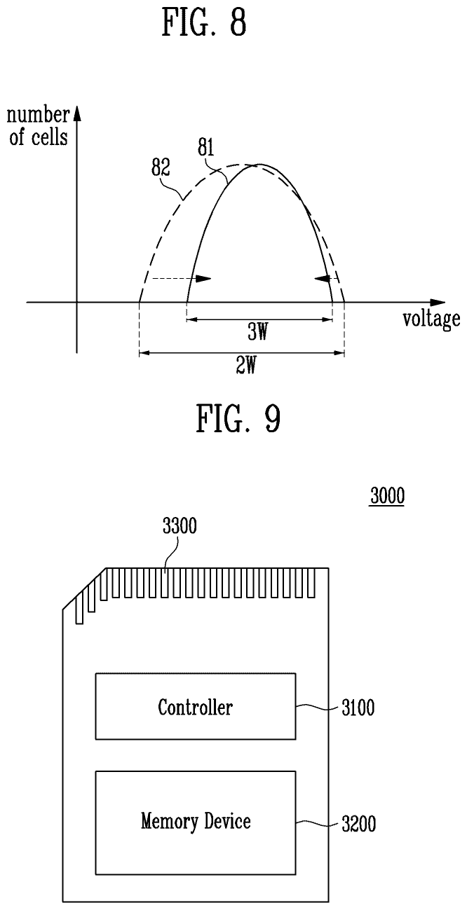

FIG. 9 is a diagram illustrating a memory card system 3000 including a memory device according to an embodiment of the present disclosure.

Referring to FIG. 9, the memory card system 3000 may include a controller 3100, a memory device 3200, and a connector 3300.

The controller 3100 may be coupled to the memory device 3200. The controller 3100 may access the memory device 3200. For example, the controller 3100 may control a program, read, or erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components, such as a Random Access Memory (RAM), a host interface, a memory interface, and an ECC circuit.

The controller 3100 may communicate with an external device through the connector 3300. The controller 3100 may communicate with an external device (e.g., a host) based on a specific communication protocol. For example, the controller 3100 may communicate with the external device through at least one of various communication standards or interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe) protocols. In an embodiment, the connector 3300 may be defined by at least one of the above-described various communication standards or interfaces.

The memory device 3200 may include a plurality of memory cells and be configured in the same manner as the memory device 100 shown in FIG. 1.

The controller 3100 and the memory device 3200 may be integrated into a single semiconductor device to form a memory card. For example, the controller 3100 and the memory device 3200 may be integrated into a single semiconductor device to form a memory card, such as a personal computer memory card international association (PCMCIA) card, a compact flash (CF) card, a smart media card (SM, or SMC), a memory stick, a multimedia card (MMC, RS-MMC, MMCmicro, or eMMC), an SD card (SD, miniSD, microSD, or SDHC), a universal flash storage (UFS), and the like.

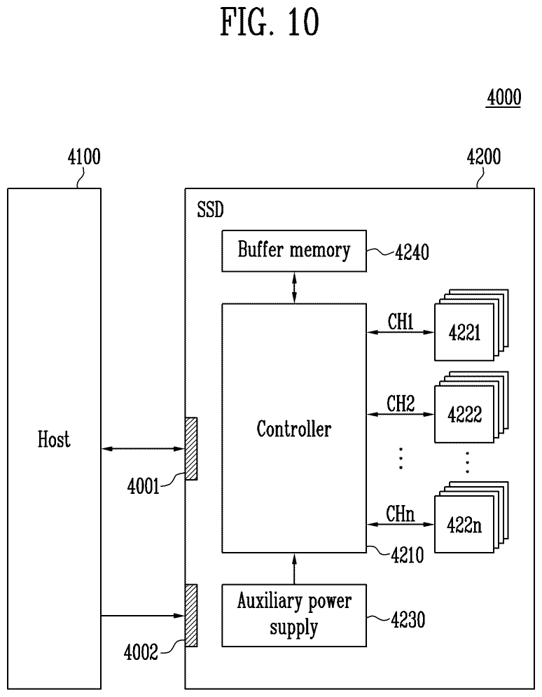

FIG. 10 is a block diagram illustrating a solid state drive (SSD) system 4000 including a memory device according to an embodiment of the present disclosure.

Referring to FIG. 10, the SSD system 4000 may include a host 4100 and an SSD 4200. The SSD 4200 may communicate with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control, through a plurality of channel CH1 to CHn, the plurality of memory devices 4221 to 422n in response to the signals received from the host 4100. In an embodiment, the signals may be based on the interfaces of the host 4100 and the SSD 4200. For example, the signals may be defined by at least one of various communication standards or interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe) interfaces.

Each of the plurality of memory devices 4221 to 422n may include a plurality of memory cells which are configured to store data. Each of the plurality of memory devices 4221 to 422n may be configured in the same manner as the memory device 100 shown in FIG. 1.

The auxiliary power supply 4230 may be coupled to the host 4100 through the power connector 4002. The auxiliary power supply 4230 may be supplied and charged with the power from the host 4100. The auxiliary power supply 4230 may supply the power of the SSD 4200 when the power is not smoothly supplied from the host 4100. In an embodiment, the auxiliary power supply 4230 may be positioned inside or outside the SSD 4200. For example, the auxiliary power supply 4230 may be disposed in a main board and supply auxiliary power to the SSD 4200.

The buffer memory 4240 may serve as a buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memories such as DRAM, SDRAM, DDR SDRAM, and LPDDR SDRAM, or nonvolatile memories such as FRAM, ReRAM, STT-MRAM, and PRAM.

According to the embodiments of the present disclosure, reliability of an erase operation performed by a memory device may be improved.

Various embodiments of the present disclosure have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims. Furthermore, the embodiments may be combined to form additional embodiments.

What is claimed is:

1. A memory device comprising:
cell strings coupled between bit lines and source lines, the cell strings including first select transistors, memory cells, and second select transistors;
first select lines coupled to the first select transistors and spaced apart from each other in a direction in which the bit lines extend;
a voltage generator configured to, during an erase operation, apply a first turn-on voltage to outer select lines among the first select lines, and apply a second turn-on voltage to inner select lines among the first select lines, the inner select lines being disposed between the outer select lines; and
a control circuit configured to control, after the first turn-on voltage reaches a target level during the erase operation, the voltage generator so that the second turn-on voltage reaches the target level.

2. The memory device of claim 1, wherein the control circuit is configured to control the voltage generator so that the first turn-on voltage and the second turn-on voltage have a same target level.

3. The memory device of claim 2, wherein the control circuit is configured to control, when an erase voltage is applied to the bit lines and the source lines, the voltage generator to
apply the first turn-on voltage to the outer select lines, and
apply the second turn-on voltage to the inner select lines.

4. The memory device of claim 3, wherein the control circuit is configured to control the voltage generator to
apply a ground voltage to the outer select lines before the first turn-on voltage is applied to the outer select lines, and
apply the ground voltage to the inner select lines before the second turn-on voltage is applied to the inner select lines.

5. The memory device of claim 1, wherein the control circuit is configured to
set a rising slope of the first turn-on voltage to have a first slope, and
set a rising slope of the second turn-on voltage to have a second slope which is lower than the first slope.

6. The memory device of claim 1, wherein the control circuit is configured to control, before the second turn-on voltage is applied to the inner select lines, the voltage generator to apply a negative voltage to the inner select lines.

7. The memory device of claim 1, wherein the first select lines are drain select lines.

8. A memory device comprising:
cell strings coupled between bit lines and source lines, the cell strings including first select transistors, memory cells, and second select transistors;
first select lines coupled to the first select transistors and spaced apart from each other in a direction in which the bit lines extend;
a voltage generator configured to, during an erase operation, apply a first turn-on voltage to outer select lines among the first select lines, and apply a second turn-on voltage to inner select lines among the first select lines, the inner select lines being disposed between the outer select lines; and
a control circuit configured to control, before the second turn-on voltage is applied to the inner select lines during the erase operation, the voltage generator to apply a negative voltage to the inner select lines.

9. The memory device of claim 8, wherein the control circuit is configured to control the voltage generator so that the first turn-on voltage and the second turn-on voltage reach a target level at a same time.

10. The memory device of claim 8, wherein the control circuit is configured to
set a rising slope of the first turn-on voltage to have a first slope, and
set a rising slope of the second turn-on voltage to have a third slope which is steeper than the first slope.

11. The memory device of claim 8, wherein the first select lines are drain select lines.

12. A method of operating a memory device, the method comprising:
applying an erase voltage to bit lines and a source line;
applying a first turn-on voltage to outer select lines among first select lines adjacent to the bit lines and arranged in a different direction from a direction in which the bit lines are arranged; and
applying a second turn-on voltage to inner select lines among the first select lines, the inner select lines being disposed between the outer select lines,
wherein the second turn-on voltage has a rising slope lower than a rising slope of the first turn-on voltage.

13. The method of claim 12, further comprising, before applying the first turn-on voltage, applying a ground voltage to the outer select lines.

14. The method of claim 12, further comprising, before applying the second turn-on voltage, applying a ground voltage to the inner select lines.

15. The method of claim 12, wherein the first and second turn-on voltages are set to have a same target level.

16. The method of claim 12, further comprising applying the first turn-on voltage to second select lines adjacent to the source line while the first turn-on voltage is applied to the outer select lines.

17. The method of claim 16, wherein the first select lines are drain select lines and the second select lines are source select lines.

18. A method of operating a memory device, the method comprising:
applying an erase voltage to bit lines and a source line;
applying a ground voltage to outer select lines among first select lines adjacent the bit lines and arranged in a different direction from a direction in which the bit lines are arranged, and applying a negative voltage to inner select lines among the first select lines, the inner select lines being disposed between the outer select lines;
applying a first turn-on voltage to the outer select lines to which the ground voltage is applied; and
applying a second turn-on voltage to the inner select lines to which the negative voltage is applied.

19. The method of claim 18, wherein the first and second turn-on voltages are set to have a same target level at a same time.

20. The method of claim 18, wherein a rising slope of the second turn-on voltage is steeper than a rising slope of the first turn-on voltage.

21. The method of claim 18, wherein the first select lines are drain select lines.
